(19) United States
(12) Patent Application Publication
(10) Pub. No.: US 2024/0282642 A1
(43) Pub. Date: Aug. 22, 2024

(54) MEASUREMENT METHOD, CONVEYANCE METHOD, ARTICLE MANUFACTURING METHOD, CONVEYANCE APPARATUS, AND LITHOGRAPHY APPARATUS

(71) Applicant: CANON KABUSHIKI KAISHA, Tokyo (JP)

(72) Inventor: KOICHI TAMURA, Tochigi (JP)

(21) Appl. No.: 18/436,154

(22) Filed: Feb. 8, 2024

(30) Foreign Application Priority Data
Feb. 20, 2023 (JP) 2023-024621

(51) Int. Cl. H01L 21/66; H01L 21/683

(52) U.S. Cl. CPC H01L 22/12; H01L 21/6838

(57) ABSTRACT

The present invention provides a measurement method of measuring a height of a hand at a start timing of contact between the hand and a substrate in a process of causing the hand to hold the substrate by moving up the hand from below the substrate, wherein the hand has an upper surface provided with a suction hole connected to a vacuum line, the method comprising: performing the process while detecting a pressure of the vacuum line; obtaining a height profile indicating a change in a height of the hand in the process; and determining a height of the hand at a second timing which is a predetermined time period before a first timing when a pressure of the vacuum line decreases and reaches a threshold, based on the height profile, as a height of the hand at the start timing.

### BACKGROUND OF THE INVENTION

### Field of the Invention

The present invention relates to a measurement method, a conveyance method, an article manufacturing method, a conveyance apparatus, and a lithography apparatus.

### Description of the Related Art

A semiconductor manufacturing apparatus or the like can be provided with a conveyance apparatus that conveys a substrate. In the conveyance apparatus, movable components such as a bearing are, for example, worn out accompanying the driving of the hand that holds a substrate, and the height position of the hand (to be sometimes written as the height of the hand hereinafter) can change over time. Such a change in the height of the hand can cause interference between a substrate and a placement portion on which the substrate is placed when the substrate is transferred between the hand and the placement portion. Accordingly, the conveyance apparatus is required to be provided with a function of measuring (monitoring) the height of the hand to periodically measure the height of the hand.

Japanese Patent Laid-Open No. 2021-129023 discloses a method of measuring the height (the position in the vertical direction) of the hand (pick) that chucks a substrate (wafer). The method disclosed in Japanese Patent Laid-Open No. 2021-129023 repeatedly executes the process of determining whether the hand has chucked a substrate in a state in which the hand is stopped upon being slid below the substrate and moved upward by a predetermined distance (for example, 0.1 mm) until the hand chucks the substrate. The height of the hand in a case where it is determined that the hand has chucked the substrate is determined as the height (the position in the vertical direction) of the hand when the lower surface of the substrate comes into contact with the upper surface of the hand.

As disclosed in Japanese Patent Laid-Open No. 2021-129023, the hand connected to an exhaust device having a vacuum pump suffers some delay from when the hand comes into contact with a substrate to when the suction pressure reaches the pressure that enables the determination of whether the substrate is chucked by the hand. Accordingly, in the method disclosed in Japanese Patent Laid-Open No. 2021-129023, whether the hand has chucked the substrate needs to be determined after a standby time equal to or more than the time required for the delay while the hand is stopped. This can lead to a disadvantage in productivity.

### SUMMARY OF THE INVENTION

The present invention provides, for example, a technique advantageous in accurately and efficiently measuring the height of a hand holding a substrate.

According to one aspect of the present invention, there is provided a measurement method of measuring a height of a hand at a start timing of contact between the hand and a substrate in a process of causing the hand to hold the substrate by moving up the hand from below the substrate, wherein the hand has an upper surface provided with a suction hole that is connected to a vacuum line, the method comprising: performing the process while detecting a pressure of the vacuum line; obtaining a height profile indicating a change in a height of the hand in the process; and determining a height of the hand at a second timing which is a predetermined time period before a first timing when a pressure of the vacuum line decreases and reaches a threshold, based on the height profile, as a height of the hand at the start timing.

Further features of the present invention will become apparent from the following description of exemplary embodiments with reference to the attached drawings.

### BRIEF DESCRIPTION OF THE DRAWINGS

FIG. 1 is a view schematically showing an example of the arrangement of a conveyance apparatus;

FIGS. 2A to 2C are views each showing an example of the arrangement of a suction mechanism in a conveyance apparatus according to the first embodiment;

FIG. 3 is a graph showing an example of a pressure profile and a height profile in a reception process;

FIG. 4 is a flowchart showing a calibration process according to the first embodiment;

FIGS. 5A and 5B are graphs showing an example of a pressure profile and a height profile obtained in the calibration process according to the first embodiment;

FIG. 6 is a graph showing information obtained by overlaying the pressure profile and the height profile obtained in the calibration process according to the first embodiment;

FIG. 7 is a graph showing a first pressure profile and a first height profile when the hand is step-driven in a first reception process;

FIG. 8 is a flowchart showing a conveyance method according to the first embodiment;

FIG. 9 is a graph showing a pressure profile and a height profile in a reception process according to the first embodiment;

FIG. 10 is a graph showing a pressure profile in a state in which a leak has occurred;

FIG. 11 is a graph showing an example of the result of conveying a flat substrate and a warped measurement substrate in a mixed state;

FIG. 12 is a view showing an example of the arrangement of a suction mechanism in a conveyance apparatus according to the second embodiment;

FIG. 13 is a flowchart showing a calibration process according to the second embodiment;

FIGS. 14A and 14B are graphs showing a pressure profile and a height profile obtained by a calibration process according to the second embodiment;

FIG. 15 is a graph showing information obtained by overlaying the pressure profile and the height profile obtained in the calibration process according to the second embodiment;

FIG. 16 is a flowchart showing a conveyance method according to the second embodiment;

FIG. 17 is a graph showing a pressure profile and a height profile in a delivery process according to the second embodiment; and

FIG. 18 is a schematic view showing an example of the arrangement of an exposure apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which the vertical direction is defined as the Z direction. Directions parallel to the X-axis, the Y-axis, and the Z-axis of the XYZ coordinate system are defined as the X direction, the Y direction, and the Z direction, respectively. A rotation about the X-axis, a rotation about the Y-axis, and a rotation about the Z-axis are defined as θX, θY, and θZ, respectively. Control and driving (movement) concerning the X-axis, the Y-axis, and the Z-axis mean control or driving (movement) concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

### First Embodiment

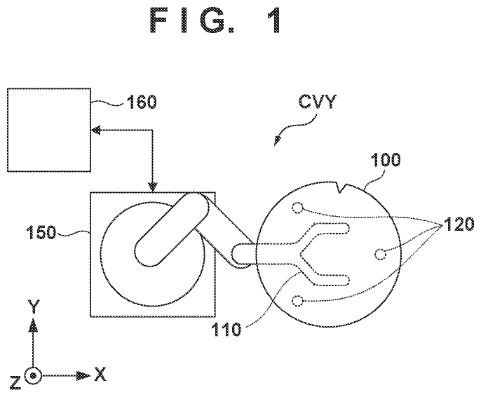

A conveyance apparatus CVY according to the first embodiment of the present invention will be described. FIG. 1 is a view schematically showing an example of the arrangement of the conveyance apparatus CVY according to this embodiment. The conveyance apparatus CVY according to this embodiment can include a hand 110 that can hold a substrate 100, a driving unit 150 (driver) that drives the hand 110, and a control unit 160 (controller). The driving unit 150 can also include a suction mechanism (exhaust mechanism) for suction-holding the substrate 100 with the hand 110 in addition to a driving mechanism that drives the hand 110 in the X, Y, and Z directions. The control unit 160 is formed from a computer (information processing apparatus) including a processor, such as a central processing unit (CPU), a storage unit, such as a memory, and the like and controls each unit of the conveyance apparatus CVY. In this embodiment, the control unit 160 controls the driving unit 150 to control the holding and conveyance of the substrate 100 by the hand 110.

In this case, the conveyance apparatus CVY according to this embodiment may be understood as a placement portion 120 on which the substrate 100 is placed. The placement portion 120 may be the conveyance destination (for example, the stage) of the substrate 100 by the conveyance apparatus CVY or a transit place (for example, a pre-alignment stage for the pre-alignment of the substrate 100) in conveying the substrate 100 to the conveyance destination. In the example shown in FIG. 1, although the placement portion 120 is constituted by three pins on which the substrate 100 is placed, the number of pins constituting the placement portion 120 is not limited to three.

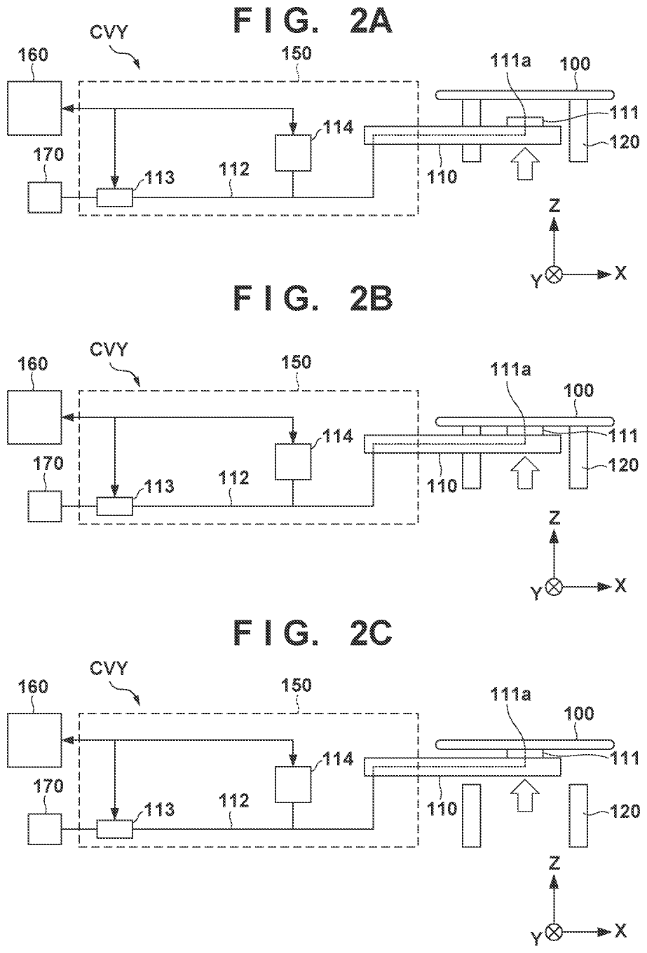

FIGS. 2A to 2C are views each showing an example of the arrangement of the suction mechanism in the conveyance apparatus CVY according to this embodiment. The hand 110 is provided with a suction pad 111 having a suction hole 111a in a surface (upper surface) that comes into contact with the substrate 100. A vacuum line 112 (a pipe) connected to a vacuum pump 170 is connected to the suction hole 111a of the suction pad 111. The vacuum line 112 is provided with an electromagnetic valve 113 for controlling the ON/OFF between the vacuum pump 170 and the vacuum line 112 and a pressure sensor 114 (a detector) that detects the pressure of the vacuum line 112. The electromagnetic valve 113 and the pressure sensor 114 are connected to the control unit 160. The control unit 160 performs ON/OFF control of the vacuum line 112 with the electromagnetic valve 113 and detects the pressure of the vacuum line 112 with the pressure sensor 114. Note that the vacuum pump 170 may be configured as a constituent element of the conveyance apparatus CVY or as an external device of the conveyance apparatus CVY.

FIGS. 2A to 2C show, with time, the process of lifting the substrate 100 from the placement portion 120 while causing the hand 110 to hold the substrate 100 by moving up the hand 110 from below the substrate 100 placed on the placement portion 120. This process may be understood as the process of causing the hand 110 to receive (obtain) the substrate 100 from the placement portion 120 and is sometimes written as “reception process” hereinafter. The reception process is performed while the pressure sensor 114 detects the pressure of the vacuum line 112. FIG. 2A shows a state in which the hand 110 has started to move up from below the substrate 100 placed on the placement portion 120. FIG. 2B shows a state in which the hand 110 has started to come into contact with the substrate 100 placed on the placement portion 120. FIG. 2C shows a state in which the hand 110 has lifted the substrate 100 from the placement portion 120 while holding the substrate 100.

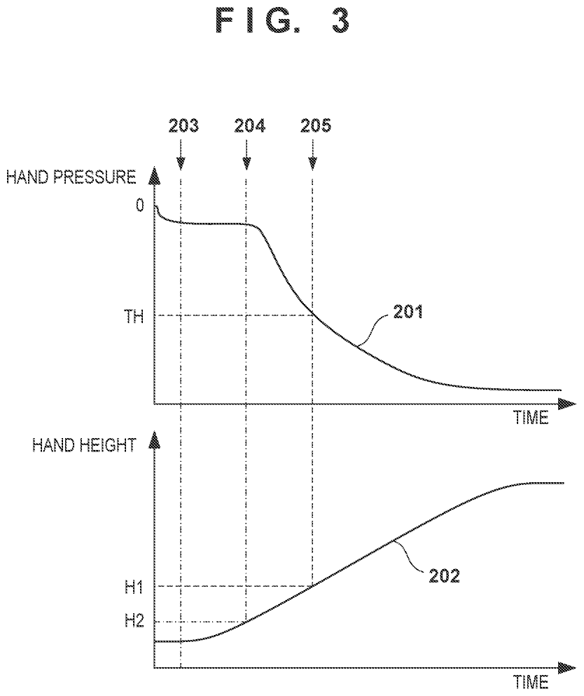

FIG. 3 shows an example of a pressure profile 201 and a height profile 202 obtained by the reception process shown in FIGS. 2A to 2C. In this embodiment, the pressure profile 201 is a profile (waveform) indicating a change in the voltage value of the vacuum line 112 detected by the pressure sensor 114 in the reception process. The ordinate of the pressure profile 201 indicates the gauge pressure. The height profile 202 is a profile (waveform) indicating a change in the height of the hand 110 in the reception process. It is possible to use, as the height of the hand 110, the detection value of a sensor (height detector) provided in the conveyance apparatus CVY so as to detect the height of the hand 110 or the value calculated from the drive amount of the hand 110 by the driving mechanism that drives the hand 110 in the Z direction. The driving mechanism that drives the hand 110 in the Z direction can be provided in the driving unit 150.

As shown in FIG. 2A, time 203 is the timing when the electromagnetic valve 113 is opened to connect the vacuum line 112 to the vacuum pump 170, and the hand 110 starts to move up from below the substrate 100 placed on the placement portion 120. At this timing, the hand 110 (the suction pad 111) is not in contact with the substrate 100, and a leak (the inflow of air) has occurred from the suction hole 111a of the hand 110 (the suction pad 111). Accordingly, the pressure value of the vacuum line 112 detected by the pressure sensor 114 remains a slight negative pressure.

As shown in FIG. 2B, time 204 is the timing when the hand 110 (the suction pad 111) has moved up to start to come into contact with the substrate 100. At this timing, although the pressure value of the vacuum line 112 detected by the pressure sensor 114 has hardly changed from that at time 203, the suction hole 111a of the suction pad 111 is closed by the substrate 100 upon contact between the suction pad 111 of the hand 110 and the substrate 100. Accordingly, the vacuum line 112 is tightly sealed to prevent a leak (the inflow of air) from the suction hole 111a. From time 204, the pressure value of the vacuum line 112 decreases (which may be understood as that the pressure value increases in the negative pressure direction).

As described above, at the timing (time 204) when the hand 110 has started to come into contact with the substrate 100, the pressure value of the vacuum line 112 has hardly changed from that at time 203. Accordingly, conventionally, the control unit 160 can only specify (grasp) the timing when the pressure value of the vacuum line 112 has reached a threshold TH based on the detection result obtained by the pressure sensor 114. However, a height H1 of the hand 110 at the timing (time 205) when the pressure value of the vacuum line 112 has reached the threshold TH shifts from a height H2 of the hand 110 at the start timing of contact between the hand 110 and the substrate 100. This shift can be about 0 mm to 3 mm depending on the ascending speed (driving speed) of the hand 110 and the state of the vacuum line 112. In addition, as disclosed in Japanese Patent Laid-Open No. 2021-129023, there is a productivity disadvantage in the method of measuring the height of the hand at the start of contact by repeating the process of determining whether the pressure value of the vacuum line 112 has reached the threshold while the hand 110 is stopped upon being moved by a predetermined distance. That is, conventionally, it is difficult to accurately and efficiently measure the height H2 of the hand 110 at the start timing of contact between the hand 110 and the substrate 100.

In this embodiment, the second timing, which is a predetermined time period before the first timing (time 205) when the pressure value of the vacuum line 112 has decreased and reached the threshold TH, is specified as the start timing (time 204) of contact between the hand 110 and the substrate 100. The height of the hand 110 at the second timing is determined as the height H2 of the hand 110 at the start timing of contact between the hand 110 and the substrate 100. In this case, the predetermined time represents the delay time from when the hand 110 comes into contact with the substrate 100 to when the pressure value of the vacuum line 112 reaches the threshold TH (to be sometimes simply written as the delay time hereinafter) and may be understood as a suction delay parameter. The delay time obtained as a transient response to the pressure value of the vacuum line 112 is uniquely determined by the exhaust performance of the vacuum pump 170 and/or the pressure loss of the vacuum line 112. Accordingly, estimating (obtaining) this delay time in advance makes it possible to accurately and efficiently measure the height H2 of the hand 110 at the start timing of contact between the hand 110 and the substrate 100.

### [Estimation of Delay Time]

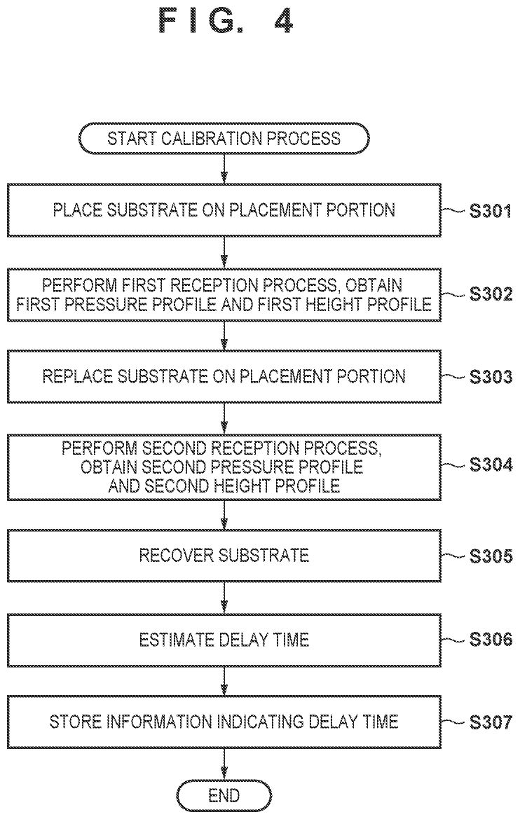

FIG. 4 is a flowchart showing a calibration process (estimation step) for estimating (obtaining) the delay time. The control unit 160 can execute the flowchart in FIG. 4 in advance before the process of actually producing a semiconductor device by using the substrate 100.

In this embodiment, there are two indefinite parameters, namely the delay time and the height of the hand 110. Accordingly, the two indefinite parameters can be calculated by setting up simultaneous equations for the two indefinite parameters from the information obtained by driving the hand 110 according to at least two types of operation patterns. The following is a description of an example of performing the first reception process (first process) and the second reception process (second process) and estimating the delay time based on the pressure profiles and the height profiles respectively obtained in the first reception process and the second reception process. Note that the first reception process and the second reception process each imitate the reception process described above.

In this case, the first reception process and the second reception process differ in the ascending speed (driving speed) of the hand 110 when it moves up. In the following example, the ascending speed of the hand 110 in the first reception process is lower than that in the second reception process. For example, in the first reception process, the hand 110 moves up at an ascending speed (first ascending speed) lower than the ascending speed used in normal conveyance, whereas in the second reception process, the hand 110 moves up at an ascending speed (second ascending speed) equal to the ascending speed used in normal conveyance. Note, however, that the ascending speed of the hand 110 in the second reception process may be lower than that in the first reception process. Note that normal conveyance can be defined as an operation for conveying the substrate 100 to a target conveyance destination by driving the hand 110.

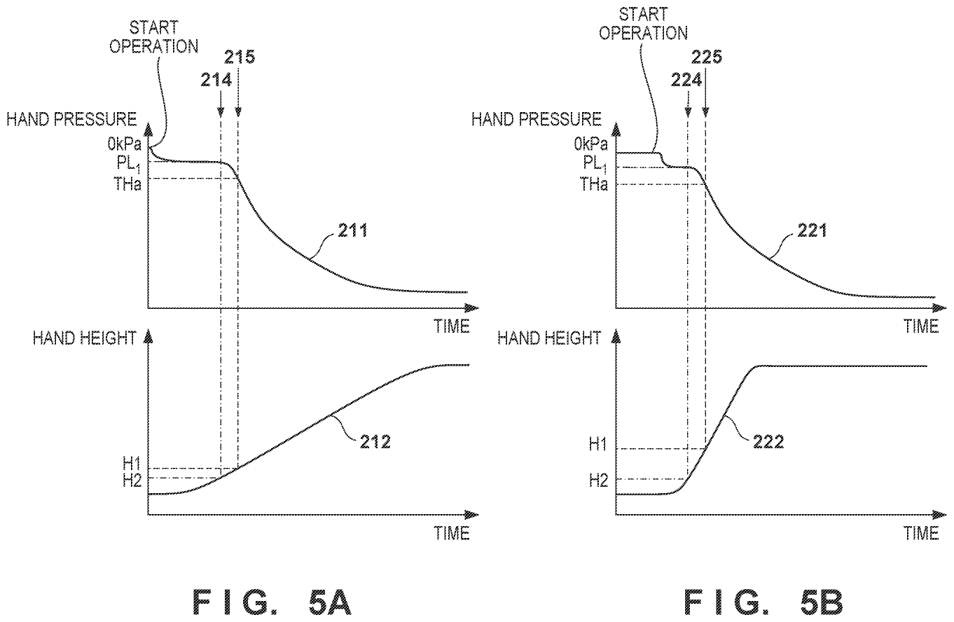

In step S301, the control unit 160 controls the driving of the hand 110 by the driving unit 150 so as to cause the hand 110 to pick up the substrate 100 from a carrier (storage section) (not shown) and convey (place) the substrate 100 onto the placement portion 120. In step S302, the control unit 160 performs the first reception process imitating the reception process. In the first reception process, the hand 110 is made to hold the substrate 100 by moving up the hand 110 from below the substrate 100 placed on the placement portion 120 at the first ascending speed. As shown in FIG. 5A, this makes it possible to obtain a pressure profile 211 and a height profile 212 in the first reception process. The pressure profile 211 is a profile indicating a change in the pressure value of the vacuum line 112 detected by the pressure sensor 114 in the first reception process and is sometimes written as the first pressure profile 211 hereinafter. In addition, the height profile 212 is a profile indicating a change in the height of the hand 110 in the first reception process and is sometimes written as the first height profile 212 hereinafter. Note that the first ascending speed can be set to a value lower than the second ascending speed for moving up the hand 110 in the second reception process (to be described later).

In step S303, the control unit 160 controls the driving of the hand 110 by the driving unit 150 so as to place again the substrate 100 held by the hand 110 through step S302 onto the placement portion 120. In step S304, the control unit 160 performs the second reception process imitating the reception process. In the second reception process, the hand 110 is made to hold the substrate 100 by moving up the hand 110 from below the substrate 100 placed on the placement portion 120 at the second ascending speed. As shown in FIG. 5B, this makes it possible to obtain a pressure profile 221 and a height profile 222 obtained in the second reception process. The pressure profile 221 is a profile indicating a change in the pressure value of the vacuum line 112 detected by the pressure sensor 114 in the second reception process and is sometimes written as the second pressure profile 221 hereinafter. In addition, the height profile 222 is a profile indicating a change in the height of the hand 110 in the second reception process and is sometimes written as the second height profile 222 hereinafter. Note that the second ascending speed can be set to a value higher than the first ascending speed for driving the hand 110 in the first reception process.

In this case, steps S301 to S304 may be repeatedly performed a plurality of times. In general, the calibration accuracy improves with the use of the results obtained by performing measurement a plurality of times. In this case, the first reception process is performed a plurality of times, and representative values (for example, average values or median values) in a plurality of first reception processes can be respectively used as the pressure profile 211 and the height profile 212 in the first reception process. Likewise, the second reception process is performed a plurality of times, and representative values (for example, average values or median values) in a plurality of second reception processes can be respectively used as the pressure profile 221 and the height profile 222 in the second reception process.

In step S305, the control unit 160 controls the driving of the hand 110 by the driving unit 150 so as to cause the hand 110 to convey the substrate 100 to the carrier (storage section) (not shown) (that is, recover the substrate 100). In step S306, the control unit 160 estimates (calculates) the delay time from when the hand 110 starts to come into contact with the substrate 100 to when the pressure value of the vacuum line 112 reaches a threshold THa. The control unit 160 estimates (calculates) the delay time based on the first pressure profile 211 and the first height profile 212 obtained in step S302 and the second pressure profile 221 and the second height profile 222 obtained in step S304. The details of a delay time estimation method (calculation method) will be described later. In step S307, the control unit 160 stores (saves) information indicating the delay time estimated in step S306 in the storage unit.

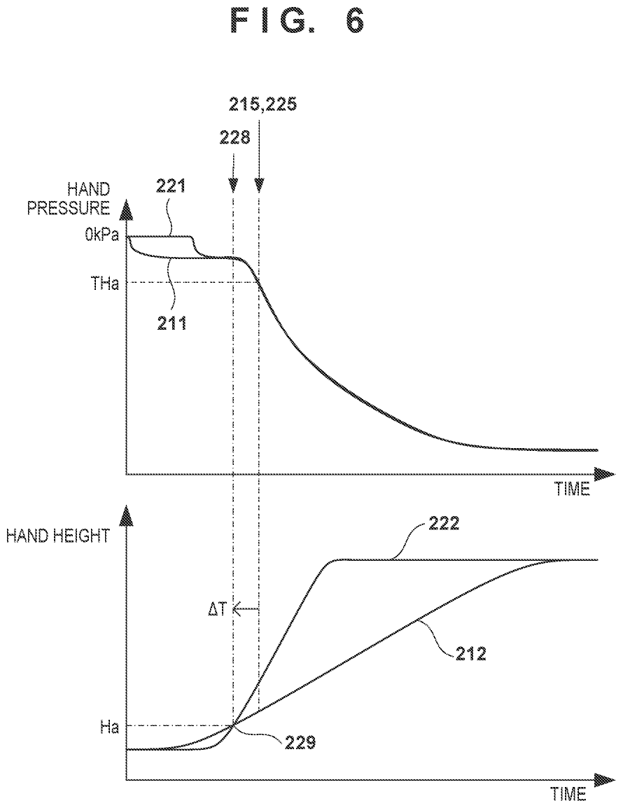

The details of the delay time estimation method in step S306 will be described next with reference to FIGS. 5A, 5B, and 6. FIG. 5A shows the first pressure profile 211 and the first height profile 212 obtained in the first reception process. FIG. 5A shows the timing (time 214) when the hand 110 has started to come into contact with the substrate 100 and the timing (time 215) when the pressure value of the vacuum line 112 connected to the hand 110 has reached the threshold THa in the first reception process. FIG. 5B shows the second pressure profile 221 and the second height profile 222 obtained in the second reception process. FIG. 5B shows the timing (time 224) when the hand 110 has started to come into contact with the substrate 100 and the timing (time 225) when the pressure value of the vacuum line 112 connected to the hand 110 has reached the threshold THa in the second reception process.

In this case, the threshold THa can be determined based on a pressure value PL₁ of the vacuum line 112 detected by the pressure sensor 114 in a state in which the hand 110 is not in contact with the substrate 100, that is, in a state in which a leak has occurred from the suction hole 111a. The pressure value PL₁ of the vacuum line 112 in a state in which a leak has occurred is substantially constant and is sometimes written as the leak state pressure PL₁ hereinafter. The leak state pressure PL₁ in the first reception process is substantially equal to that in the second reception process, and hence the threshold THa can be determined to be a value commonly used in the first reception process and the second reception process. For example, the threshold THa may be determined to be a value offset from the leak state pressure PL₁ by a predetermined amount or may be determined to be the value obtained by multiplying the leak state pressure PL₁ by a predetermined gain. Since the leak state pressure PL₁ is influenced by a variation in the performance of an exhaust mechanism such as the vacuum pump 170 or the vacuum line 112, the pressure value on the source pressure side (for example, the pressure value generated by the vacuum pump 170) may be obtained, and the threshold THa may be determined in accordance with the pressure value on the source pressure side. In addition, the threshold THa may be determined to be a value as close as possible to the leak state pressure PL₁ of a portion where the pressure value of the pressure profile steeply changes. This makes it possible to reduce the influence of a variation in the performance of the exhaust mechanism. Note that when the pressure sensor 114 is in the switch output mode, since the pressure sensor 114 can be used only at a predetermined value set in advance for the sensor, the predetermined value may be determined as the threshold THa.

In each of the first reception process and the second reception process, it is difficult to specify the timing (time 214 or time 224) when the hand 110 has started to come into contact with the substrate 100 based on the pressure value of the vacuum line 112 detected by the pressure sensor 114. For this reason, in this embodiment, the delay time is estimated based on information obtained by overlaying the first height profile 212 and the second height profile 222 such that the arrival times (time 215 and time 225) when the pressure of the vacuum line 112 has reached the threshold THa coincide with each other. More specifically, the time (intersection time) corresponding to the intersection point between the first height profile 212 and the second height profile 222 is obtained, and the difference between the time corresponding to the intersection point and the arrival time is estimated as the delay time.

FIG. 6 shows the information (waveform) obtained by overlaying the pressure profiles (211 and 221) and the height profiles (212 and 222) in FIGS. 5A and 5B. In this information, the first pressure profile 211 and the second pressure profile 221 are overlaid each other such that the arrival times (time 215 and time 225) when the pressure of the vacuum line 112 has reached the threshold THa coincide with each other. In this case, the first pressure profile 211 and the second pressure profile 221 exhibit substantially the same waveform from the arrival times (time 215 and time 225) when the pressure of the vacuum line 112 has reached the threshold THa. Likewise, in the information, the first height profile 212 and the second height profile 222 are overlaid each other such that the arrival times (time 215 and time 225) when the pressure of the vacuum line 112 has reached the threshold THa coincide with each other. An intersection point 229 between the first height profile 212 and the second height profile 222 at this time becomes a height Ha of the hand 110 when the hand 110 starts to come into contact with the substrate 100. Accordingly, the difference between time 228 (intersection time) corresponding to the intersection point 229 and the arrival time (time 215 and time 225) can be estimated (calculated) as a delay time ΔT.

The delay time ΔT is a value unique to the conveyance apparatus CVY, and hence the above calibration process needs to be performed only once. If, however, the state of the conveyance apparatus CVY may change, such as an increase in leak due to the wear of the suction pad 111 accompanying the driving of the hand 110, the above calibration process may be periodically executed. In addition, if the delay time ΔT has undergone a change over time of a predetermined value or more in a periodic calibration process, it is determined that some abnormality has occurred in the conveyance apparatus CVY. In this case, the user may be notified of the corresponding information, or the operation of the conveyance apparatus CVY may be stopped.

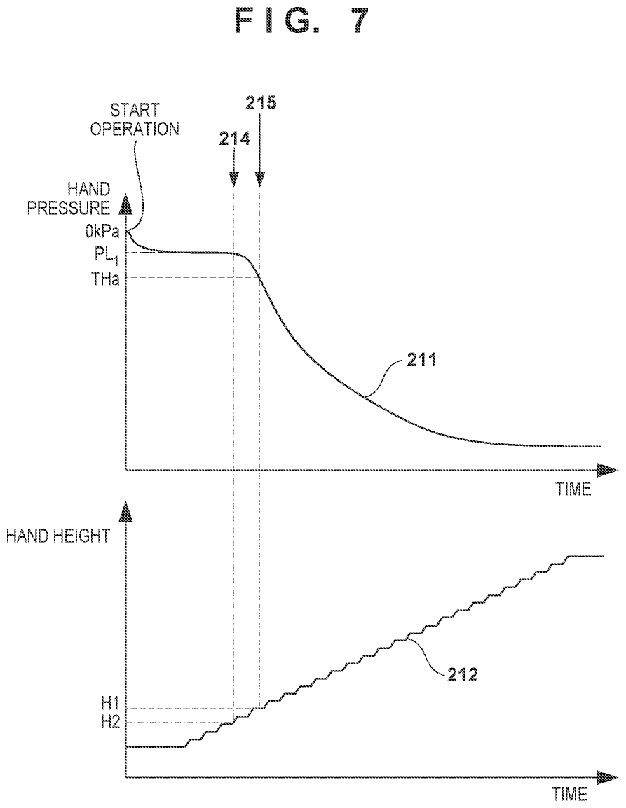

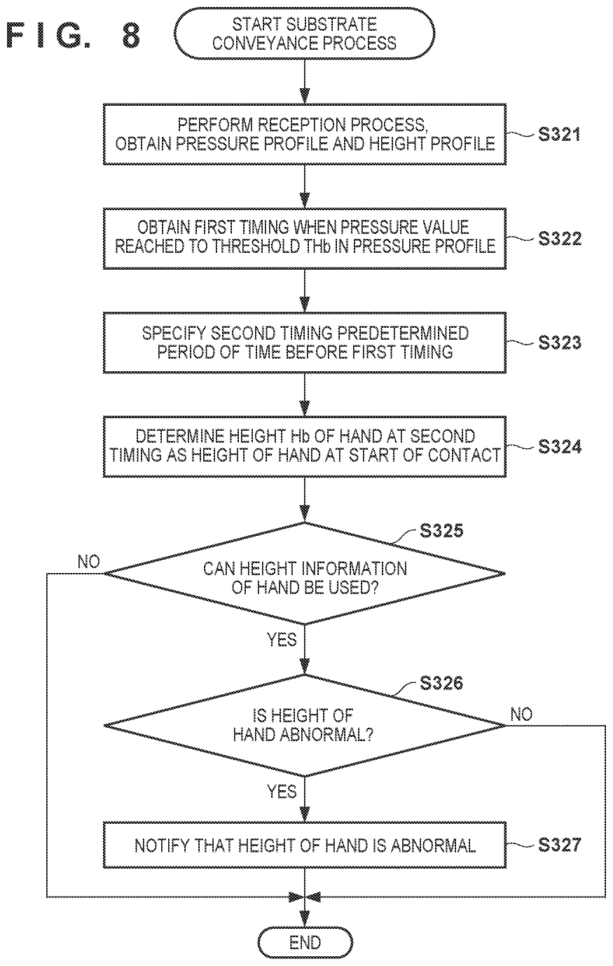

In this case, in the calibration process, the hand 110 may be step-driven in at least one of the first reception process and the second reception process. FIG. 7 shows the first pressure profile 211 and the first height profile 212 when the hand 110 is step-driven in the first reception process. Step-driving is to drive the hand 110 so as to change the height of the hand 110 in steps of a predetermined distance. As described above, even if the hand 110 is step-driven, the intersection point 229 between the first height profile 212 and the second height profile 222 becomes the height of the hand 110 when the hand 110 starts to come into contact with the substrate 100. Accordingly, in this case as well, the difference between time 228 corresponding to the intersection point 229 and the arrival time (time 215 or time 225) can be estimated (calculated) as the delay time ΔT.

Note that as a delay time estimation method, there is conceivable a method of estimating the delay time from the differentiated waveform (differential value) of a pressure profile, in addition to the above calibration process in this embodiment. However, in the method using differentiated waveforms, after the start of contact between the hand 110 (suction pad 111) and the substrate 100, the substrate 100 repeatedly contacts and non-contacts the suction pad 111. This may cause erroneous detection of a fluctuating pressure change. In addition, a differentiated waveform is susceptible to exhaust performance variation, and obtained delay times can vary more than in this embodiment. Accordingly, using the delay time estimation method according to this embodiment can estimate the delay time more accurately than using the method of estimating the delay time using differentiated waveforms, and hence is more advantageous.

### [Conveyance Method for Substrate Using Hand]

A method (conveyance method) of performing normal conveyance of the substrate 100 using the hand 110 will be described next. As described above, normal conveyance can be an operation for conveying the substrate 100 to a target conveyance destination by driving the hand 110. FIG. 8 is a flowchart showing the conveyance method for the substrate 100 using the hand 110. The control unit 160 can execute the flowchart in FIG. 8. In this case, steps S321 to S324 in the flowchart in FIG. 8 correspond to the measurement step (measurement process) of measuring the height of the hand 110 at the start timing of contact between the hand 110 and the substrate 100 in the reception process. Steps S325 to S327 correspond to the monitoring step of monitoring the height of the hand 110 based on the measurement result obtained in the measurement step. The flowchart in FIG. 8 can be understood as processes (steps) performed during the execution of normal conveyance. In addition, the calibration process (estimation step) shown in the flowchart in FIG. 4 may be added to the measurement step.

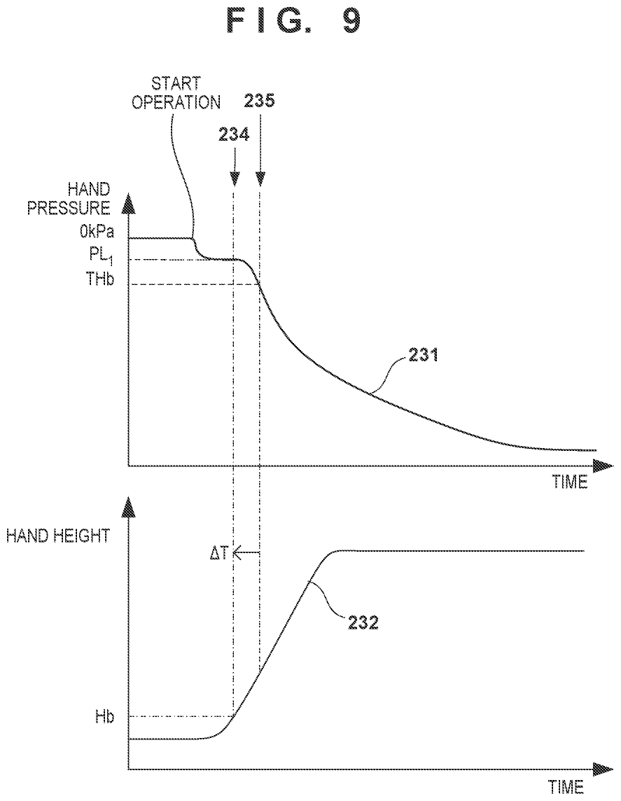

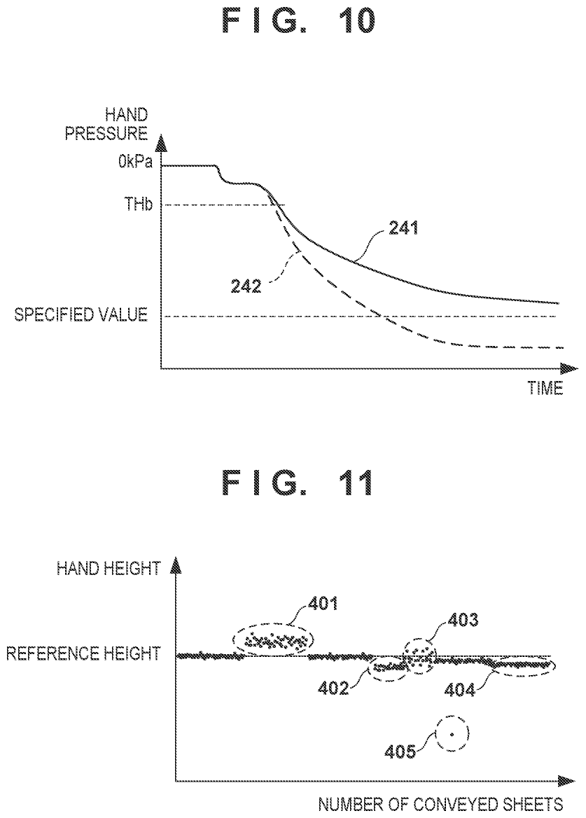

In step S321, the control unit 160 performs a reception process and obtains a pressure profile 231 and a height profile 232 in the reception process. FIG. 9 shows the pressure profile 231 and the height profile 232 in the reception process. The pressure profile 231 is a profile indicating a change in the pressure value of the vacuum line 112 detected by the pressure sensor 114 in the reception process. The height profile 232 is a profile indicating a change in the height of the hand 110 in the reception process.

In step S322, the control unit 160 obtains the first timing (time 235) when the pressure value of the vacuum line 112 has reached a threshold THb in the pressure profile 231 obtained in step S321. The threshold THb used in step S322 can be determined to be the same value as the threshold THa used in the above calibration process. For example, the threshold THb used in step S322 may be determined to be a value offset from the leak state pressure PL₁ by a predetermined amount or may be determined to be the value obtained by multiplying the leak state pressure PL₁ by a predetermined gain as in the calibration process described above. The leak state pressure PL₁ is constant unless the arrangement of the driving unit 150 (suction mechanism) is changed, and hence the threshold THb calculated with reference to the leak state pressure PL₁ can be the same value as the threshold THa used in the calibration process.

In step S323, the control unit 160 specifies the second timing (time 234) which is a predetermined time period before the first timing obtained in step S322 is specified as the timing when the hand 110 has started to come into contact with the substrate 100 in the reception process. As the predetermined time period, the delay time ΔT estimated in the above calibration process can be used. Subsequently, in step S324, the control unit 160 determines a height Hb of the hand 110 at the second timing (time 234) in the height profile 232 as the height of the hand 110 at the start timing of contact between the hand 110 and the substrate 100 in the reception process.

In step S325, the control unit 160 determines whether the height information of the hand 110 obtained in step S324 can be used to determine a height abnormality in the hand 110. As measurement error factors in normal conveyance, there are conceivable a case where a suction process has taken a long time upon repeated contact and non-contact of part of the substrate 100 with respect to the suction pad 111, a case where the substrate 100 has warped, and the like. Detecting such an error factor can improve the accuracy of the determination of the height abnormality of the hand 110. If it is determined that the height information of the hand 110 obtained in step S324 can be used for the determination of the height abnormality of the hand 110, the process advances to step S326. If it is determined that the height information cannot be used for the determination of the height abnormality of the hand 110, the processing is terminated.

FIG. 10 shows a pressure profile 241 in a state in which a minute leak (the inflow of air) has occurred from the suction hole 111a to the vacuum line 112 after the reception of the substrate 100 by the hand 110. The minute leak after the reception of the substrate 100 by the hand 110 can occur if the suction hole 111a of the suction pad 111 is not satisfactorily sealed by the substrate 100 to fail in tightly sealing the vacuum line 112 due to the influences of the posture, warpage, vibration, and the like of the substrate 100. The pressure profile 241 in a state in which the minute leak has occurred indicates that the pressure value of the vacuum line 112 does not completely decrease as compared with a pressure profile 242 in a normal state (that is, a state in which no leak has occurred), as shown in FIG. 10. For this reason, with the pressure profile 241 in a state in which a minute leak has occurred, it is not possible to accurately measure the height of the hand 110, and hence it can be difficult to accurately determine the height abnormality of the hand 110. For this reason, the control unit 160 determines whether the height information of the hand 110 obtained in step S324 can be used for the determination of the height abnormality of the hand 110 in accordance with whether the pressure value of the vacuum line 112 falls below a specified value in a reception process. More specifically, if the pressure value of the vacuum line 112 falls below the specified value in the reception process, it is determined that the height information of the hand 110 can be used. In contrast to this, if the pressure value of the vacuum line 112 does not fall below the specified value in the reception process, it is determined that the height information of the hand 110 cannot be used. The specified value can be set to a value lower than the threshold THb, for example, a value that is not reached in a state in which a leak has occurred but is reached in a state in which no leak has occurred.

In step S326, the control unit 160 determines whether the height of the hand 110 is abnormal based on the height information of the hand 110 obtained in step S324. If, for example, the height Hb of the hand 110 obtained in step S324 falls within the allowable range, the control unit 160 determines that the height of the hand 110 is normal and terminates the processing. In contrast to this, if the height Hb of the hand 110 obtained in step S324 falls outside the allowable range, the control unit 160 determines that the height of the hand 110 is abnormal, and the process advances to step S327. In step S327, the control unit 160 notifies the user that the height of the hand 110 is abnormal. This notification can be performed via a user interface provided in the conveyance apparatus CVY.

The determination of whether the height information of the hand 110 with respect to the warpage of the substrate 100 can be used (step S325) will be described here. If the warpage amount of the substrate 100 is known, the influence of the warpage of the substrate 100 can be removed by using only the height information of the hand 110 which falls within a predetermined range. In addition, if the warpage amount of the substrate 100 is unknown, it is possible to statistically determine whether a given measurement result can be used for each lot of substrates by comparison with past measurement results. FIG. 11 shows an example of the result of conveying flat substrates and warped measurement substrates in a mixed state. Substrates having heights substantially equal to the reference height are flat substrates, and the remaining substrates are warped substrates. For example, groups 401 and 402 are determined as warped substrates because the measurement results are offset from flat substrates, and hence it can be determined that the height information cannot be used (cannot be adopted). A group 403 exhibits heights substantially equal to the reference height on average, but the heights vary widely, and hence it can be determined that the height information cannot be used (cannot be adopted). A group 404 exhibits slight offsets, but the measurement results vary slightly, and hence it can be determined that the height information can be used because an influence by the substrate warpage is small.

The determination of whether the height of the hand 110 is abnormal (step S326) will be described. Although the determination of the height abnormality of the hand 110 may be performed based on the measurement result obtained in each case, since the measurement results tend to vary over a long span of time, the determination may be performed by using the moving average, median value, or the like of past measurement results, as shown in FIG. 11. In addition, if an abnormal value like a group 405 is detected separately from the determination of the height abnormality of the hand 110, it may be determined that the warpage amount of the substrate 100 is excessively large, and there is an interference risk at the time of conveyance with respect to the succeeding substrate. Accordingly, in this case, it may be determined that a corresponding notification should be made to the user or the conveyance should be stopped.

As described above, this embodiment is configured to specify the second timing a predetermined time of period before the first timing when the pressure value of the vacuum line 112 connected to the suction hole 111a of the hand 110 decreases and reaches the threshold THb. The height Hb of the hand 110 at the second timing is determined as the height of the hand 110 at the start timing of contact between the hand 110 and the substrate 100 based on the height profile of the hand 110 in the reception process. This makes it possible to accurately and efficiently measure the height of the hand 110 in normal conveyance without separately providing the process of only measuring the height of the hand 110.

### Second Embodiment

A conveyance apparatus CVY according to the second embodiment of the present invention will be described. This embodiment basically inherits the first embodiment and can comply with the first embodiment except for matters to be described below.

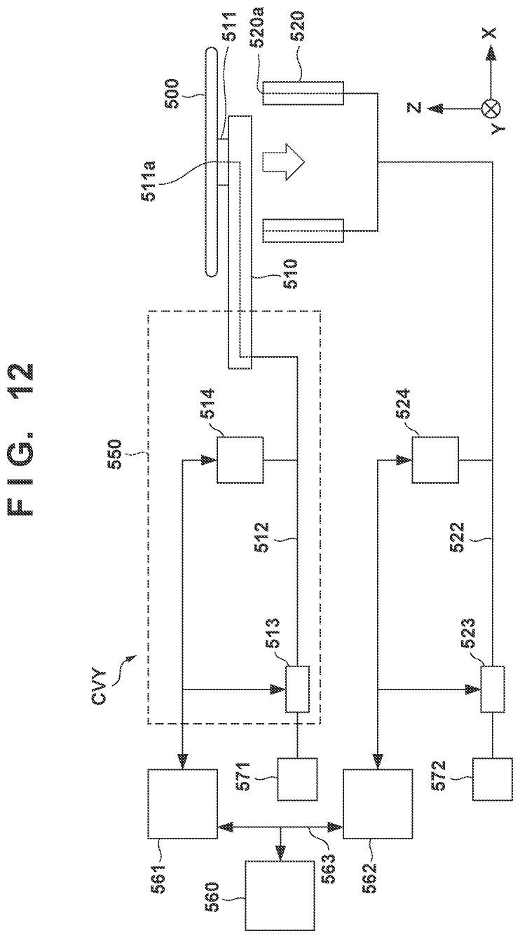

FIG. 12 is a view showing an example of the arrangement of a suction mechanism in the conveyance apparatus CVY according to this embodiment. A driving unit 550 controls a hand 510. The driving unit 550 can include a suction mechanism (exhaust mechanism) for suction-holding a substrate 500 with the hand 510 in addition to a driving mechanism that drives the hand 510 in the X, Y, and Z directions. The hand 510 is provided with a suction pad 511 having a suction hole 511a in the surface (upper surface) that comes into contact with the substrate 500. A vacuum line 512 (pipe) connected to a vacuum pump 571 is connected to the suction hole 511a of the suction pad 511. The vacuum line 512 is provided with an electromagnetic valve 513 for controlling the ON/OFF between the vacuum pump 571 and the vacuum line 512 and a pressure sensor 514 (detector) that detects the pressure of the vacuum line 512. The electromagnetic valve 513 and the pressure sensor 514 are connected to a control unit 561. The control unit 561 performs ON/OFF control of the vacuum line 512 with the electromagnetic valve 513 and detects the pressure of the vacuum line 512 with the pressure sensor 514. Note that the vacuum pump 571 may be configured as a constituent element of the conveyance apparatus CVY or as an external device of the conveyance apparatus CVY.

A placement portion 520 on which the substrate 500 is placed is configured to suction-hold the substrate 500 in this embodiment. The upper surface of the placement portion 520 is provided with a suction hole 520a. A vacuum line 522 (pipe) connected to a vacuum pump 572 is connected to the suction hole 520a. The vacuum line 522 is provided with an electromagnetic valve 523 for controlling the ON/OFF between the vacuum pump 572 and the vacuum line 522 and a pressure sensor 524 (detector) that detects the pressure of the vacuum line 522. The electromagnetic valve 523 and the pressure sensor 524 are connected to a control unit 562. The control unit 562 performs the ON/OFF control of the vacuum line 522 with the electromagnetic valve 523 and detects the pressure of the vacuum line 522 with the pressure sensor 524. Note that the vacuum pump 572 may be configured as a constituent element of the conveyance apparatus CVY or as an external device of the conveyance apparatus CVY. In addition, the vacuum pumps 571 and 572 may be configured as the same unit.

The control units 561 and 562 are communicably connected to a main control unit 560 (high-order controller) via a communication line 563. The main control unit 560 controls the holding and conveyance of the substrate 500 with the hand 110 as well as performing the control of the control units 561 and 562 and transmission and reception of data and information between the control unit 561 and the control unit 562. The main control unit 560 and the control units 561 and 562 each can be formed from a computer (information processing apparatus) including a processor such as a central processing unit (CPU) and a storage unit such as a memory. Note that the main control unit 560 and the control units 561 and 562 may be configured as one control unit.

In the conveyance apparatus CVY according to this embodiment, in the process of delivering the substrate 500 from the hand 510 to the placement portion 520, the height of the hand 510 at the start timing of contact between the placement portion 520 and the substrate 500 is measured. In this process, while the vacuum line 522 connected to the suction hole 520a of the placement portion 520 is connected to the vacuum pump 572, the hand 510 holding the substrate 500 is lowered from above the placement portion 520 to place the substrate 500 on the placement portion 520 and cause the placement portion 520 to hold the substrate 500. This processing is sometimes written as a “delivery process” hereinafter. The delivery process is performed while the pressure of the vacuum line 522 is detected by the pressure sensor 524.

### [Estimation of Delay Time]

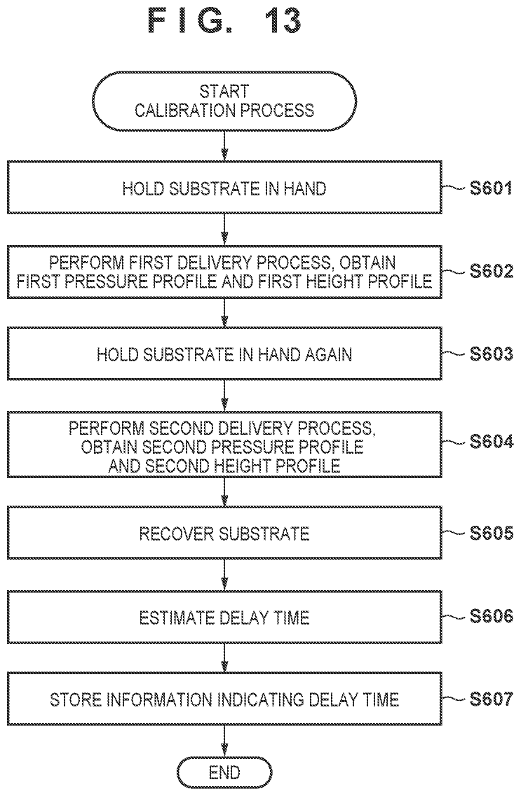

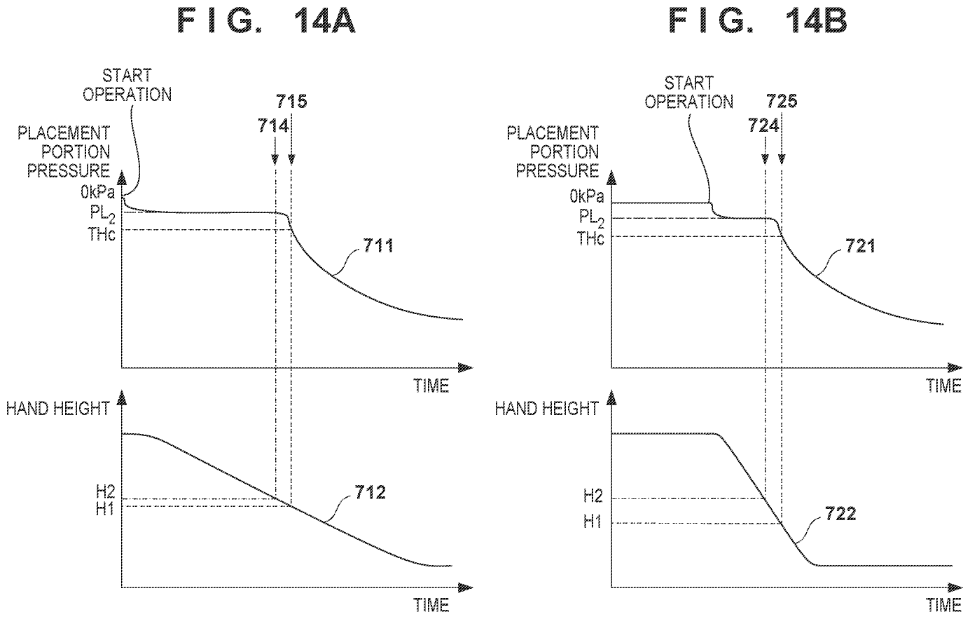

A calibration process (estimation step) for estimating (obtaining) the delay time in this embodiment will be described next. FIG. 13 is a flowchart showing a calibration process according to the embodiment. The main control unit 560 can execute the flowchart in FIG. 13 before the process of actually producing a semiconductor device or the like by using the substrate 500. The following is a description of an example of performing the first delivery process (first process) and the second delivery process (second process) and estimating the delay time based on the pressure profile and the height profile obtained in each of the first delivery process and the second delivery process. A pressure profile in this embodiment is a profile indicating a change in the pressure value of the vacuum line 522 connected to the suction hole 520a of the placement portion 520 and can be obtained based on the detection result obtained by the pressure sensor 524. A height profile in the embodiment is a profile indicating a change in the height of the hand 510. Note that the first reception process and the second reception process each imitate the reception process described above.

In this case, the first delivery process and the second delivery process differ in the descending speed (driving speed) of the hand 510 when it moves down. In the following example, the descending speed of the hand 510 in the first delivery process is lower than that in the second delivery process. For example, in the first delivery process, the hand 510 moves down at a descending speed (first descending speed) lower than the descending speed used in normal conveyance, whereas in the second delivery process, the hand 510 moves down at a descending speed (second descending speed) equal to the descending speed used in normal conveyance. Note, however, that the descending speed of the hand 510 in the second delivery process may be lower than that in the first delivery process. Note that normal conveyance can be defined as an operation for conveying the substrate 500 to a target conveyance destination by driving the hand 510.

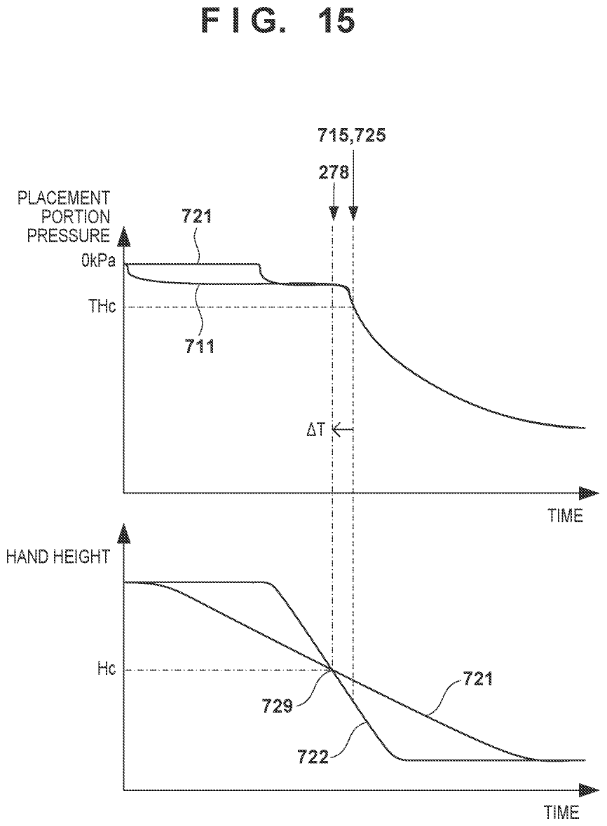

In step S601, the main control unit 560 controls the driving of the hand 510 by the driving unit 550 so as to cause the hand 510 to pick up the substrate 500 from a carrier (storage section) (not shown) and hold the substrate 500. In step S602, the main control unit 560 performs the first delivery process imitating the delivery process. In the first delivery process, the hand 510 holding the substrate 500 is made to move down from above the placement portion 520 at the first descending speed (first driving speed) so as to place and hold the substrate 500 on the placement portion 520. As shown in FIG. 14A, this makes it possible to obtain a pressure profile 711 and a height profile 712 in the first delivery process. The pressure profile 711 is a profile indicating a change in the pressure value of the vacuum line 522 detected by the pressure sensor 524 in the first delivery process and is sometimes written as the first pressure profile 711 hereinafter. In addition, the height profile 712 is a profile indicating a change in the height of the hand 510 in the first delivery process and is sometimes written as the second height profile 712 hereinafter. Note that the first descending speed can be set to a value lower than the second descending speed for moving down the hand 510 in the second delivery process (to be described later).

In step S603, the main control unit 560 controls the driving of the hand 510 by the driving unit 150 so as to cause the hand 510 to hold again the substrate 500 held by the placement portion 520 through step S502. In step S604, the main control unit 560 performs the second delivery process imitating the delivery process. In the second delivery process, the hand 510 holding the substrate 500 is moved down from above the placement portion 520 at a second descending speed (second driving speed) to place and hold the substrate 500 on the placement portion 520. As shown in FIG. 14B, this makes it possible to obtain a pressure profile 721 and a height profile 722 in the second delivery process. The pressure profile 721 is a profile indicating a change in the pressure value of the vacuum line 522 detected by the pressure sensor 524 in the second delivery process and is sometimes written as the second pressure profile 721 hereinafter. In addition, the height profile 722 is a profile indicating a change in the height of the hand 510 in the second delivery process and is sometimes written as the second height profile 722 hereinafter. Note that the second descending speed can be set to a value higher than the first descending speed for moving down the hand 510 in the first delivery process.

In this case, steps S601 to S604 may be repeatedly performed a plurality of times. In general, the calibration accuracy improves with the use of the results obtained by performing measurement a plurality of times. In this case, the first delivery process is performed a plurality of times, and representative values (for example, average values or median values) in a plurality of first delivery processes can be respectively used as the pressure profile 711 and the height profile 712 in the first delivery process. Likewise, the second delivery process is performed a plurality of times, and representative values (for example, average values or median values) in a plurality of second delivery processes can be respectively used as the pressure profile 721 and the height profile 722 in the second delivery process.

In step S605, the main control unit 560 controls the driving of the hand 510 by the driving unit 550 so as to cause the hand 510 to convey the substrate 500 to the carrier (storage section) (not shown) by recovering the substrate 500 from the placement portion 520. In step S606, the main control unit 560 estimates (calculates) the delay time from when the placement portion 520 starts to come into contact with the substrate 500 to when the pressure value of the vacuum line 522 reaches a threshold THc. The main control unit 560 estimates (calculates) the delay time based on the first pressure profile 711 and the first height profile 712 obtained in step S602 and the second pressure profile 721 and the second height profile 722 obtained in step S604. The details of a delay time estimation method (calculation method) will be described later. In step S607, the main control unit 560 stores (saves) information indicating the delay time estimated in step S606 in the storage unit.

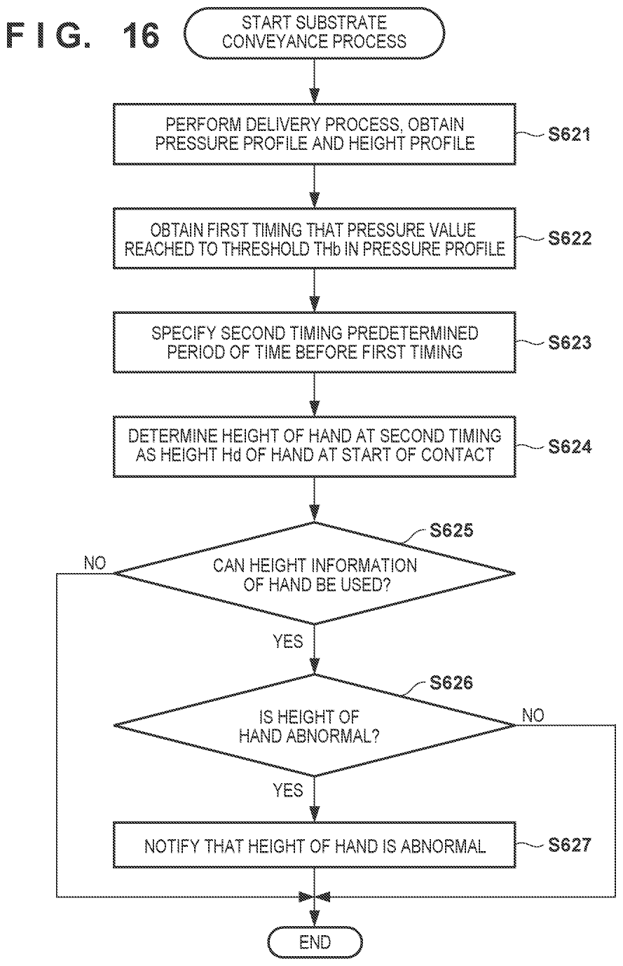

The details of the delay time estimation method in step S606 will be described next with reference to FIGS. 14A, 14B, and 15. FIG. 14A shows the first pressure profile 711 and the first height profile 712 obtained in the first delivery process. FIG. 14A shows the timing (time 714) when the placement portion 520 has started to come into contact with the substrate 500 and the timing (time 715) when the pressure value of the vacuum line 522 connected to the placement portion 520 has reached the threshold THc in the first delivery process. FIG. 14B shows the second pressure profile 721 and the second height profile 722 obtained in the second delivery process. FIG. 14B shows the timing (time 724) when the placement portion 520 has started to come into contact with the substrate 500 and the timing (time 725) when the pressure value of the vacuum line 522 connected to the placement portion 520 has reached the threshold THc in the second delivery process.

In this case, the threshold THc can be determined based on a pressure value PL₂ of the vacuum line 522 detected by the pressure sensor 524 in a state in which the placement portion 520 is not in contact with the substrate 500, that is, in a state in which a leak has occurred from the suction hole 520a. The pressure value PL₂ of the vacuum line 522 in a state in which a leak has occurred is substantially constant and is sometimes written as the leak state pressure PL₂ hereinafter. The leak state pressure PL₂ in the first delivery process is substantially equal to that in the second delivery process, and hence the threshold THc can be determined to be a value commonly used in the first delivery process and the second delivery process. For example, the threshold THc may be determined to be a value offset from the leak state pressure PL₂ by a predetermined amount or may be determined to be the value obtained by multiplying the leak state pressure PL₂ by a predetermined gain. Since the leak state pressure PL₂ is influenced by a variation in the performance of an exhaust mechanism such as the vacuum pump 572 or the vacuum line 522, the pressure value on the source pressure side (for example, the pressure value generated by the vacuum pump 572) may be obtained, and the threshold THc may be determined in accordance with the source pressure value on the source pressure side. More specifically, the threshold THc may be determined to be a value as close as possible to the leak state pressure PL₂ of a portion where the pressure value of the pressure profile steeply changes. This makes it possible to reduce the influence of a variation in the performance of the exhaust mechanism. Note that when the pressure sensor 524 is in the switch output mode, since the pressure sensor 524 can be used only at a predetermined value set in advance for the sensor, the predetermined value may be determined as the threshold THc.

In each of the first delivery process and the second delivery process, it is difficult to specify the timing (time 714 or time 724) when the placement portion 520 starts to come into contact with the substrate 500 based on the pressure value of the vacuum line 522 detected by the pressure sensor 524. For this reason, in this embodiment, the delay time is estimated based on information obtained by overlaying the first height profile 712 and the second height profile 722 such that the arrival times (time 715 and time 725) when the pressure of the vacuum line 522 has reached the threshold THc coincide with each other. More specifically, the time (intersection time) corresponding to the intersection point between the first height profile 712 and the second height profile 722 is obtained, and the difference between the time corresponding to the intersection point and the arrival time is estimated as the delay time.

FIG. 15 shows the information (waveform) obtained by overlaying the pressure profiles (711 and 721) and the height profiles (712 and 722) in FIGS. 14A and 14B. In this information, the first pressure profile 711 and the second pressure profile 721 are overlaid each other such that the arrival times (time 715 and time 725) when the pressure of the vacuum line 522 has reached the threshold THc coincide with each other. In this case, the first pressure profile 711 and the second pressure profile 721 exhibit substantially the same waveform from the arrival times (time 715 and time 725) when the pressure of the vacuum line 522 has reached the threshold THc. Likewise, in the information, the first height profile 712 and the second height profile 722 are overlaid each other such that the arrival times (time 715 and time 725) when the pressure of the vacuum line 522 has reached the threshold THc coincide with each other. An intersection point 729 between the first height profile 712 and the second height profile 722 at this time becomes a height Hc of the hand 510 when the placement portion 520 starts to come into contact with the substrate 500. Accordingly, the difference between time 728 (intersection time) corresponding to the intersection point 729 and the arrival time (time 715 or time 725) can be estimated (calculated) as the delay time ΔT.

As described above, the second embodiment differs from the first embodiment in that the reception processes are replaced with the delivery processes, and the detection of the suction pressure of the hand is replaced with the detection of the suction pressure of the placement portion. Note that the basic method of estimating the delay time ΔT in the first embodiment is the same as that in the second embodiment.

### [Conveyance Method for Substrate Using Hand]

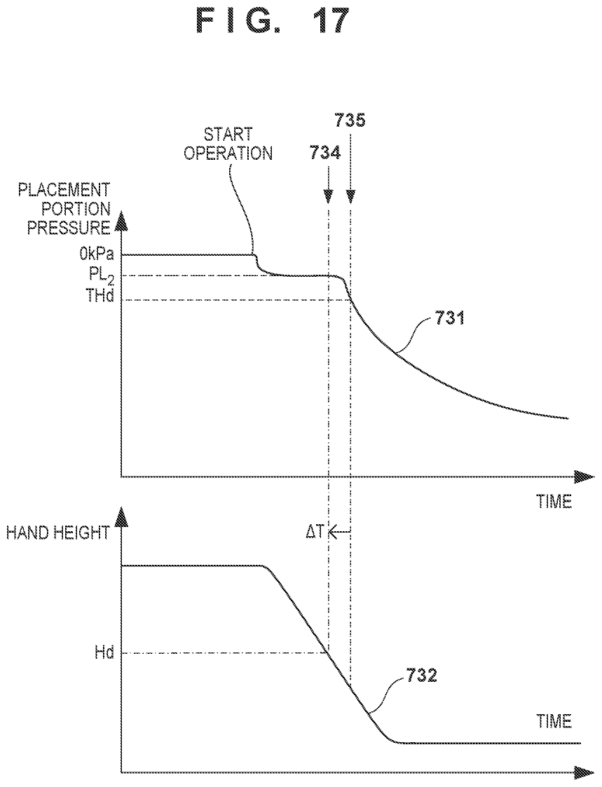

A method (conveyance method) of performing normal conveyance of the substrate 500 using the hand 510 will be described next. As described above, normal conveyance can be an operation for conveying the substrate 500 to a target conveyance destination by driving the hand 510. FIG. 16 is a flowchart showing the conveyance method for the substrate 500 using the hand 510. The main control unit 560 can execute the flowchart in FIG. 16. In this case, steps S621 to S624 in the flowchart in FIG. 16 correspond to the measurement step (measurement process) of measuring the height of the hand 510 at the start timing of contact between the placement portion 520 and the substrate 500 in the delivery process. Steps S625 to S627 correspond to the monitoring step of monitoring the height of the hand 510 based on the measurement result obtained in the measurement step. The flowchart in FIG. 16 can be understood as processes (steps) performed during the execution of normal conveyance. In addition, the calibration process (estimation step) shown in the flowchart in FIG. 13 may be added to the measurement step.

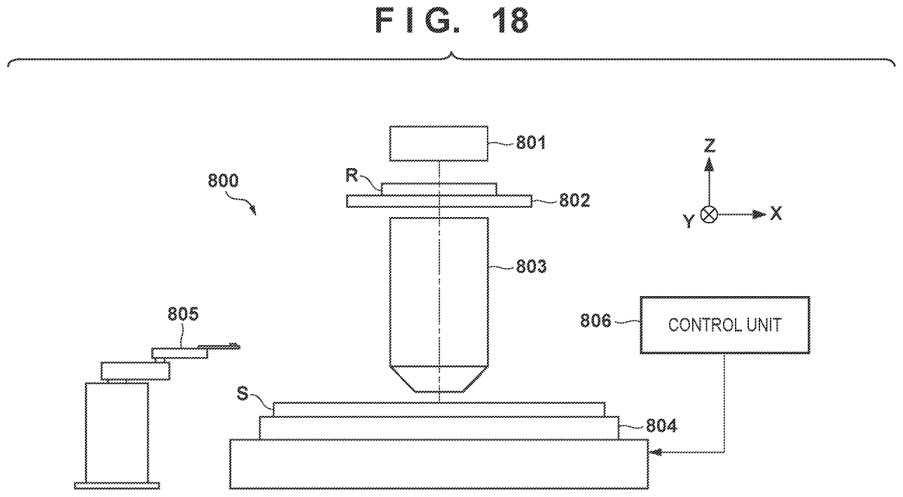

In step S621, the main control unit 560 performs a delivery process and obtains a pressure profile 731 and a height profile 732 in the delivery process. FIG. 17 shows the pressure profile 731 and the height profile 732 in the delivery process. The pressure profile 731 is a profile indicating a change in the pressure value of the vacuum line 522 connected to the suction hole 520a of the placement portion 520 and can be obtained based on the detection result obtained by the pressure sensor 524 in the delivery process. The height profile 732 is a profile indicating a change in the height of the hand 510.

In step S622, the main control unit 560 obtains the first timing (time 235) when the pressure value of the vacuum line 522 has reached the threshold THd in the pressure profile 731 obtained in step S621. The threshold THd used in step S622 can be determined to be the same value as the threshold THc used in the above calibration process.

In step S623, the main control unit 560 specifies the second timing (time 734) which is a predetermined time period before the first timing obtained in step S622 as the timing when the placement portion 520 has started to come into contact with the substrate 500 in the delivery process. As the predetermined time period, the delay time ΔT estimated in the above calibration process can be used. Subsequently, in step S624, the main control unit 560 determines the height Hd of the hand 510 at the second timing (time 734) in the height profile 732 as the height of the hand 510 at the start timing of contact between the placement portion 520 and the substrate 500 in the delivery process.

In step S625, the main control unit 560 determines whether the height information of the hand 510 obtained in step S624 can be used to determine a height abnormality in the hand 510. In step S626, the main control unit 560 determines based on the height information of the hand 510 obtained in step S624 whether the height of the hand 510 is abnormal. If, for example, the height Hd of the hand 510 obtained in step S624 falls within the allowable range, the main control unit 560 determines that the height of the hand 510 is normal and terminates the processing. In contrast to this, if the height Hd of the hand 510 obtained in step S624 falls outside the allowable range, the main control unit 560 determines that the height of the hand 510 is abnormal, and the process advances to step S627. In step S627, the main control unit 560 notifies the user that the height of the hand 510 is abnormal. Since steps S625 to S627 are similar to steps S325 to S327 in FIG. 8 described in the first embodiment, a detailed description of the steps will be omitted.

As described above, this embodiment is configured to specify the second timing a predetermined time of period before the first timing when the pressure value of the vacuum line 522 connected to the suction hole 520a of the hand 520 decreases and reaches the threshold THd. The height Hd of the hand 510 at the second timing is determined as the height of the hand 510 at the start timing of contact between the placement portion 520 and the substrate 500 based on the height profile of the hand 510 in the delivery process. This makes it possible to accurately and efficiently measure the height of the hand 510 in normal conveyance without separately providing the process of only measuring the height of the hand 510.

### <Embodiment of Lithography Apparatus>

An embodiment of a lithography apparatus according to the present invention will be described. The lithography apparatus is an apparatus that is used for a lithography process as a manufacturing process for a semiconductor device or liquid crystal display device and forms a pattern on a substrate. As a lithography apparatus, there is available an exposure apparatus that transfers a pattern of an original onto a substrate by exposing the substrate to light through the original, an imprint apparatus that forms a pattern of an imprint material on a substrate by using a mold, or the like. The following will exemplify an exposure apparatus as a lithography apparatus.

FIG. 18 is a schematic view showing an example of the arrangement of an exposure apparatus 800. The exposure apparatus 800 transfers the pattern formed on an original R onto a substrate S by, for example, a step-and-repeat scheme or step-and-scan scheme. As shown in FIG. 18, the exposure apparatus 800 includes an illumination optical system 801, an original stage 802, a projection optical system 803, a substrate stage 804, a conveyance apparatus 805, and a control unit 806. In the exposure apparatus 800, the illumination optical system 801, the original stage 802, the projection optical system 803, and the substrate stage 804 function as a forming device that forms a pattern on a substrate S.

The illumination optical system 801 illuminates the original R with light emitted from a light source (not shown). A pattern (for example, a circuit pattern) that is, formed from, for example, silica glass and should be transferred onto the substrate S is formed on the original R. The original stage 802 moves in each direction along the X-axis and the Y-axis while holding the original R. The projection optical system 803 projects the pattern of the original R illuminated by the illumination optical system 801 onto the substrate S at a predetermined magnification (for example, ½ times). The substrate S is a substrate made of, for example, single-crystal silicon and has a surface coated with a resist (photosensitive agent). The substrate stage 804 moves in each direction along the X-axis and the Y-axis while holding the substrate S. The control unit 806 is formed from a computer including, for example, a CPU and a memory and comprehensively controls the respective units of the exposure apparatus 800 in accordance with programs.

The exposure apparatus 800 is provided with the conveyance apparatus 805 that conveys the substrate S to the substrate stage 804. As the conveyance apparatus 805, the conveyance apparatus CVY described in the first or second embodiment can be used. In this case, the control unit 806 of the exposure apparatus 800 may have an arrangement including the control unit of the conveyance apparatus CVY.

### <Embodiment of Method of Manufacturing Article>

The lithography apparatus as described above can be used to perform an article manufacturing method for manufacturing various articles (for example, a semiconductor IC device, a liquid crystal display device, and MEMS). A method of manufacturing an article according to an embodiment of the present invention is suitable for manufacturing, for example, an article such as a device (a semiconductor device, a magnetic storage medium, or a liquid crystal display device). This manufacturing method includes a conveyance step of conveying a substrate by using the above conveyance apparatus (conveyance method), a forming step of forming a pattern on a substrate conveyed in the conveyance step, a processing step of processing the substrate having undergone the forming step, a manufacturing step of manufacturing an article from the substrate having undergone the processing step. This manufacturing method further includes other known steps (oxidation, deposition, vapor deposition, doping, planarization, etching, resist removal, dicing, bonding, packaging, and the like). The method of manufacturing the article according to this embodiment is advantageous in at least one of the performance, the quality, the productivity, and the production cost of the article, as compared with a conventional method.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-024621 filed on Feb. 20, 2023, which is hereby incorporated by reference herein in its entirety.

What is claimed is:

1. A measurement method of measuring a height of a hand at a start timing of contact between the hand and a substrate in a process of causing the hand to hold the substrate by moving up the hand from below the substrate, wherein the hand has an upper surface provided with a suction hole that is connected to a vacuum line, the method comprising:
performing the process while detecting a pressure of the vacuum line;
obtaining a height profile indicating a change in a height of the hand in the process; and
determining a height of the hand at a second timing which is a predetermined time period before a first timing when a pressure of the vacuum line decreases and reaches a threshold, based on the height profile, as a height of the hand at the start timing.

2. The measurement method according to claim 1, wherein
the predetermined time period represents a delay time from when the hand and the substrate start to come into contact with each other in the process to when the pressure of the vacuum line reaches the threshold, and
the measurement method further comprises estimating the delay time.

3. The measurement method according to claim 2, wherein
the estimating includes
performing a first process and a second process, each imitating the process, to obtain a first height profile indicating a change in the height of the hand in the first process and a second height profile indicating a change in the height of the hand in the second process, and
estimating, as the delay time, a difference between an intersection time and an arrival time based on information obtained by overlaying the first height profile and the second height profile so as to make the arrival time in the first height profile coincide with the arrival time in the second height profile, the intersection time being a time corresponding to an intersection point between the first height profile and the second height profile, and the arrival time being a time when the pressure of the vacuum line reaches the threshold, and
the first process differs from the second process in a driving speed of the hand.

4. The measurement method according to claim 1, wherein the process includes causing the hand to hold the substrate and lift the substrate from the placement portion, by moving up the hand from below the substrate placed on the placement portion.

5. The measurement method according to claim 1, wherein the upper surface of the hand having the suction hole is a surface that comes into contact with the substrate.

6. A measurement method of measuring a height of a hand at a start timing of contact between a placement portion and a substrate in a process of placing and holding the substrate on the placement portion by moving down the hand holding the substrate from above the placement portion, wherein the placement portion has an upper surface provided with a suction hole that is connected to a vacuum line, the method comprising:
performing the process while detecting a pressure of a vacuum line;
obtaining a height profile indicating a change in a height of the hand in the process; and
determining a height of the hand at a second timing which is a predetermined time period before a first timing when a pressure of the vacuum line decreases and reaches a threshold, based on the height profile, as a height of the hand at the start timing.

7. A conveyance method of conveying a substrate with a hand, the method comprising:
measuring a height of the hand by using a measurement method defined in claim 1; and
monitoring a height of the hand based on a measurement result obtained in the measuring.

8. The conveyance method according to claim 7, wherein the monitoring includes determining whether the height of the hand is abnormal, and notifying corresponding information in a case where the height of the hand is determined to be abnormal.

9. The conveyance method according to claim 8, wherein
the determining whether the height of the hand is abnormal in the monitoring is executed in a case where the pressure of the vacuum line falls below a specified value in the process, and
the specified value is set to a value lower than the threshold.

10. An article manufacturing method comprising:
conveying a substrate by using a conveyance method defined in claim 7;
forming a pattern on the conveyed substrate;
processing the substrate on which the pattern has been formed; and
manufacturing an article from the processed substrate.

11. A conveyance apparatus for conveying a substrate, the apparatus comprising:
a hand having an upper surface provided with a suction hole that is connected to a vacuum line;
a detector configured to detect a pressure of the vacuum line; and
a controller configured to control holding and conveyance of the substrate with the hand,
wherein the controller monitors the height of the hand based on a measurement result obtained by measuring the height of the hand at a start timing of contact between the hand and the substrate in a process of causing the hand to hold the substrate by moving up the hand from below the substrate, and
wherein the measuring the height of the hand includes
performing the process while causing the detector to detect the pressure of the vacuum line,
obtaining a height profile indicating a change in the height of the hand in the process, and
determining the height of the hand at a second timing which is a predetermined time period before a first timing when a pressure of the vacuum line decreases and reaches a threshold, based on the height profile, as a height of the hand at the start timing.

12. A lithography apparatus for forming a pattern on a substrate, the apparatus comprising:
a conveyance apparatus defined in claim 11 and configured to convey the substrate; and
a forming device configured to form a pattern on the substrate conveyed by the conveyance apparatus.

13. A conveyance apparatus for conveying a substrate, the apparatus comprising:
a hand configured to hold the substrate;
a placement portion having an upper surface provided with a suction hole that is connected to a vacuum line;
a detector configured to detect a pressure of the vacuum line; and
a controller configured to control conveyance of the substrate with the hand,
wherein the controller monitors the height of the hand based on a measurement result obtained by measuring the height of the hand at a start timing of contact between the placement portion and the substrate in a process of placing and holding the substrate on the placement portion by moving down the hand holding the substrate from above the placement portion, and
wherein the measuring the height of the hand includes
performing the process while causing the detector to detect the pressure of the vacuum line,
obtaining a height profile indicating a change in the height of the hand in the process, and
determining the height of the hand at a second timing which is a predetermined time period before a first timing when a pressure of the vacuum line decreases and reaches a threshold, based on the height profile, as a height of the hand at the start timing.

14. A lithography apparatus for forming a pattern on a substrate, the apparatus comprising:
a conveyance apparatus defined in claim 13 and configured to convey the substrate; and
a forming device configured to form a pattern on the substrate conveyed by the conveyance apparatus.
